(19) United States
(12) Patent Application Publication
(10) Pub. No.: US 2024/0224478 A1
(43) Pub. Date: Jul. 4, 2024

(54) ELECTRIC DEVICE WITH RADIOACTIVE PAINT

(71) Applicant: MILWAUKEE ELECTRIC TOOL CORPORATION, Brookfield, WI (US)

(72) Inventor: Anil Kumar Vangara, Chicago, IL (US)

(21) Appl. No.: 18/483,097

(22) Filed: Oct. 9, 2023

Related U.S. Application Data
(60) Provisional application No. 63/417,447, filed on Oct. 19, 2022.

(51) Int. Cl. H05K 7/20

(52) U.S. Cl. CPC H05K 7/209; H05K 7/2039

(57) ABSTRACT

An electric device includes a housing having an exterior surface exposed to a surrounding environment, an interior volume defined in the housing, and an electronic component disposed in the interior volume and configured to generate heat. At least a portion of the exterior surface emits infrared rays in a wavelength range of 8 to 13 micrometers to release heat into the surrounding environment.

### CROSS-REFERENCE TO RELATED APPLICATIONS

The present disclosure claims priority to U.S. Provisional Patent Application No. 63/417,447, filed Oct. 19, 2022, the entire contents of which are hereby incorporated by reference herein.

### FIELD OF THE DISCLOSURE

The present disclosure relates to electric devices. More particularly, the present disclosure relates to electric devices such as battery packs, outdoor power tools, and handheld power tools.

### BACKGROUND OF THE DISCLOSURE

Electric devices, such as power tools and battery packs, are often operated in hot environments. Heat from the surrounding environment can be absorbed by a housing of the electric device. The absorbed heat can then transfer into an interior volume of the housing and increase the temperature of mechanical and electrical components housed within the electric device.

### SUMMARY OF THE DISCLOSURE

The present disclosure provides, in one aspect, an electric device including a housing having an exterior surface exposed to a surrounding environment, an interior volume defined in the housing, and an electronic component disposed in the interior volume and configured to generate heat. At least a portion of the exterior surface emits infrared rays in a wavelength range of 8 to 13 micrometers to release heat into the surrounding environment.

The present disclosure provides, in another aspect, an electric device including a housing having an exterior surface exposed to a surrounding environment, an interior volume defined in the housing, and an electronic component disposed in the interior volume and configured to generate heat. At least a portion of the exterior surface emits infrared rays in a wavelength range of 8 to 13 micrometers. The portion of the exterior surface includes at least one of Al₂O₂, SiO₂, and Si₃N₄ nanoparticles.

The present disclosure provides, in another aspect, an electric device including a housing having an exterior surface exposed to a surrounding environment, an interior volume defined in the housing, and an electronic component disposed in the interior volume and configured to generate heat. At least a portion of the exterior surface emits infrared rays in a wavelength range of 8 to 13 micrometers to release heat into the surrounding environment. The portion of the exterior surface includes at least one of Al₂O₂, SiO₂, CaSO₄, c-BN, ZrO₂, MgHPO₄, Ta₂O₅, AlN, LiF, MgF₂, HfO₂, and BaSO₄ nanoparticles mixed with a polymeric binder and a paint.

### BRIEF DESCRIPTION OF DRAWINGS

FIG. 1 is schematic view of a nanoparticle.

FIG. 2 is a perspective view of a lawnmower.

FIG. 3 is an enlarged view of the lawnmower of FIG. 2.

FIG. 4 is a side elevation cross-sectional view of a portion of the lawnmower of FIG. 2.

FIG. 5 is a first side perspective view of a chainsaw.

FIG. 6 is a second side perspective view of the chainsaw of FIG. 5.

FIG. 7 is a side elevation cross-sectional view of a portion of the chainsaw of FIG. 5.

FIG. 8 is a perspective view of a handheld blower.

FIG. 9 is an enlarged perspective view of the handheld blower of FIG. 8.

FIG. 10 is a top perspective view of a hedge trimmer.

FIG. 11 is a bottom perspective view of the hedge trimmer of FIG. 10.

FIG. 12 is a perspective view of a string trimmer.

FIG. 13 is an enlarged perspective view of a portion of the string trimmer of FIG. 12.

FIG. 14 is a first side perspective view of a battery pack.

FIG. 15 is a second side perspective view of the battery pack of FIG. 14.

FIG. 16 is a top perspective view of a battery charger.

Before any embodiments of the disclosure are explained in detail, it is to be understood that the disclosure is not limited in its application to the details of construction and the arrangement of components set forth in the following description or illustrated in the drawings. The disclosure is capable of other embodiments and of being practiced or of being carried out in various ways. Also, it is to be understood that the phraseology and terminology used herein is for the purpose of description and should not be regarded as limiting.

### DETAILED DESCRIPTION

Radioactive nanoparticles suspended in a matrix can be provided to perform passive daytime radiative cooling (PDRC) on an exterior surface defined by a housing of an electric device. PDRC permits the exterior surface to reduce the amount of energy transferred into the housing of the electric device. Electrical and mechanical components supported within an interior volume of the housing are then less likely to overheat due to the heat from the surrounding environment. As such, temporary or permanent damages and degradation to the life cycle of the mechanical and electrical components are less likely.

The radioactive nanoparticles are configured to emit infrared rays to reduce the amount of energy that reaches the exterior surface of the electric device. Specifically, the radioactive particles emit infrared rays (IR) at a first wavelength range between 8 and 13 micrometers. The IR rays emitted in the first wavelength range are not absorbed by the Earth's atmosphere. The radioactive nanoparticles can be suspended in a matrix, such as paint, a thin film, plastic components that form particular components of the electric device, and etc. Many of the embodiments herein will be discussed with reference to the paint, however other matrices can apply just as well to the embodiments discussed herein below.

A radioactive paint can be composed of paint mixed with at least one of Al₂O₂, SiO₂, and Si₃N₄ nanoparticles and a polymeric binder, such as dipentarythritol penta-hexa-acrylate (DPHA). In some embodiments, the radioactive paint is composed of at least one of Al₂O₂, SiO₂, and CaSO₄, c-BN, ZrO₂, MgHPO₄, Ta₂O₅, AlN, LiF, MgF₂, HfO₂, and BaSO₄ nanoparticles. In other embodiments, the polymeric binder can be polytetrafluoroethylene (PTFE), poly urethane acrylate (PUA), ethylene tetra fluoro ethylene (ETFE), polyvinylidene fluoride (PVDF), acrylic polymers, polyester polymers, or polyurethane polymers. Different compositions and thicknesses of the radioactive paint can be formed to respectively obtain preferred emissivity and absorptivity values in an atmospheric transparency window and a solar spectral region. The atmospheric transparency window is defined by the first wavelength range, 8 to 13 micrometers. The solar spectral region is a second wavelength range between 0.3 and 2.5 micrometers. To effectively perform PDRC, the nanoparticle materials must have low absorptivity (a) in the solar spectral region and high emissivity (8) in the atmospheric transparency window.

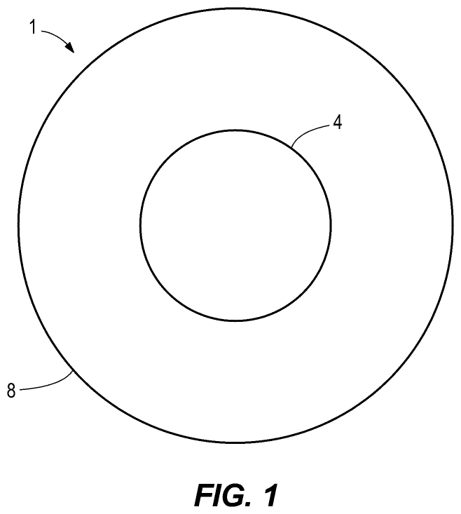

In reference to FIG. 1, a nanoparticle 1 is illustrated as being formed by a core 4 and an outer layer 8. The core 4 and the outer layer 8 can be formed of different radioactive nanoparticles. A volumetric ratio or molecular ratio can be used to define the radioactive nanoparticles. The combination of nanoparticles provides different emissivity and absorptivity values that can be combined to improve the overall emissivity and the absorptivity of the radioactive paint. In addition, the nanoparticles can provide various high extinction coefficients (k) to also produce high emissivity. The k value of a nanoparticle demonstrates the nanoparticles' ability to absorb or reflect electromagnetic waves at a specific wavelength range. In this case, the nanoparticle defines specific k values that can be combined to provide the radioactive paint with different k values throughout the atmospheric transparency window. As such, the radioactive paint can have high k values throughout the atmospheric transparency window to produce different high emissivity values throughout the atmospheric transparency window. The polymeric binder used within the radioactive paint can also have a high k value in the atmospheric transparency window to further improve the emissivity of the radioactive paint. The nanoparticles used within the radioactive paint also have a high bandgap energy to ensure that the radioactive paint absorbs less sunlight, in comparison to a paint with nanoparticles having a low bandgap energy.

The radioactive paint is a passive cooling technology. Therefore, the radioactive paint does not consume any external power that could be provided by an electric device. The heat provided by the surrounding environment and the composition of the radioactive paint are enough to produce PDRC.

A net cooling power (Pₙₑₜ) of the radioactive paint is used to define the radioactive paint's ability to perform PDRC. Altering the composition of the nanoparticles used within the radioactive paint can provide a desired Pₙₑₜ. The Pₙₑₜ of the radioactive paint is calculated using Equation 1.

$${P}_{net} ( T ) = {P}_{rad} ( T ) - {P}_{atm} ( {T}_{atm} ) - {P}_{sun} ( T ) - {P}_{nonrad} \qquad Equation 1$$

Prad(T) defines the emitted hemispheric radiation power from the exterior surface of an electric device and is calculated using Equation 2. Patm(Tatm) defines the power loss by absorbing atmospheric emission of the exterior surface of an electric device and is calculated using Equation 3. Pₛᵤₙ defines the power loss by solar absorption and is calculated using Equation 4. P_{nonrad} defines power loss due to conduction and convention and is calculated using Equation 5.

$${P}_{rad} ( T ) = {\int }_{0}^{2 π} {\int }_{0}^{\frac{π}{2}} {\int }_{0}^{∞} {I}_{BB} ( T , λ ) ε ( λ , θ ) {ε}_{atm} ( λ , θ ) cos θ sin θ d λ d θ d φ \qquad Equation 2$$

$${P}_{atm} ( {T}_{atm} ) = {\int }_{0}^{2 π} {\int }_{0}^{\frac{π}{2}} {\int }_{0}^{∞} {I}_{BB} ( {T}_{atm} , λ ) ε ( λ , θ ) {ε}_{atm} ( λ , θ ) cos θ sin θ d λ d θ d φ \qquad Equation 3$$

$${P}_{sun} = {\int }_{0}^{∞} {I}_{AM 1.5} ( λ ) ε ( λ , θ ) d λ \qquad Equation 4$$

$${P}_{nonrad} = {h}_{c} ( {T}_{atm} - T ) \qquad Equation 5$$

A cooling temperature (ΔT_{cool}) of the radioactive paint is also used to define the PDRC performance of the radioactive paint. To effectively perform PDRC, the cooling temperature must show that the exterior surface of an electric device is at a temperature below the ambient temperature of the surrounding environment. This demonstrates that the radioactive paint is capable of cooling the exterior surface to a temperature below the ambient temperature. Equation 6 is used to calculate the cooling temperature.

$$Δ {T}_{cool} = {T}_{amb} - T \qquad Equation 6$$

In other embodiments of the radioactive paint, thermally conductive nanoparticles can be included to provide a thermally conductive radioactive paint. The radioactive paint includes at least one of h-BN, Si₃N₄, Y₂O₃, BeO, and MgO nanoparticles. As such, the thermally conductive nanoparticles increase the thermal conductivity of the radioactive paint. Increasing the thermal conductivity of the radioactive paint allows heat to be transferred from an electronic component, configured to generate heat and housed within a housing of an electric device, to the radioactive paint. The transferred heat can then be released by the radioactive paint.

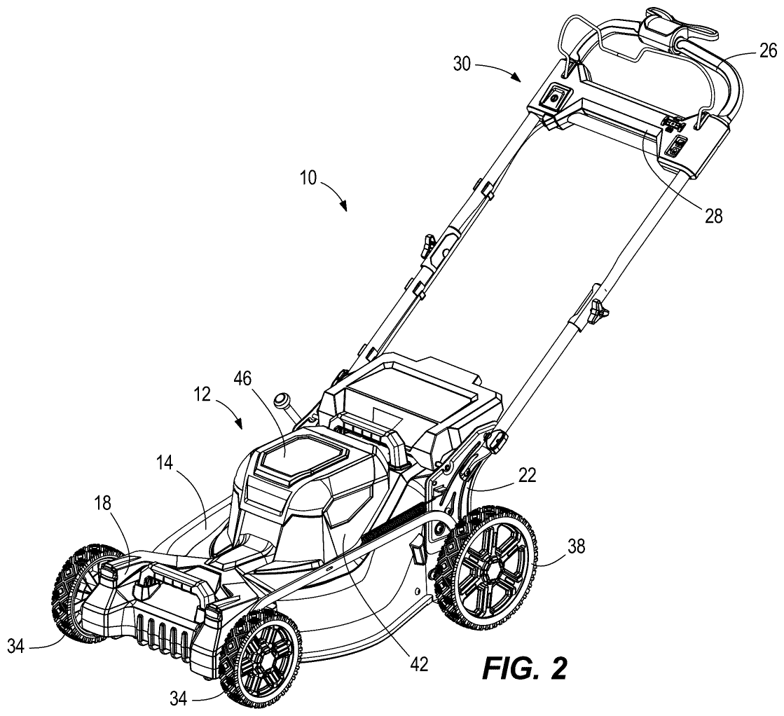

FIG. 2 illustrates an embodiment of an electric device, such as a lawnmower 10, or a walk-behind lawnmower. The lawnmower 10 includes a housing 12, which defines an exterior surface of the lawnmower 10, formed by a deck 14 and a front frame 18 coupled to a front end portion of the deck 14, a pair of brackets 22 coupled to a rear end portion of the deck 14, a handle 30 coupled to the brackets 22, and a rear guard (not shown) also coupled to the rear end portion of the deck 14. The handle 30 includes a gripping portion 26 and a panel 28 positioned below the gripping portion 26. The panel 28 of the handle 30 includes controls for operating the lawnmower 10. The deck 14 is supported by a pair of front wheels 34 and a pair of rear wheels 38, each rotatable about an axle, such that the deck 14 can be rolled along a grass surface during use.

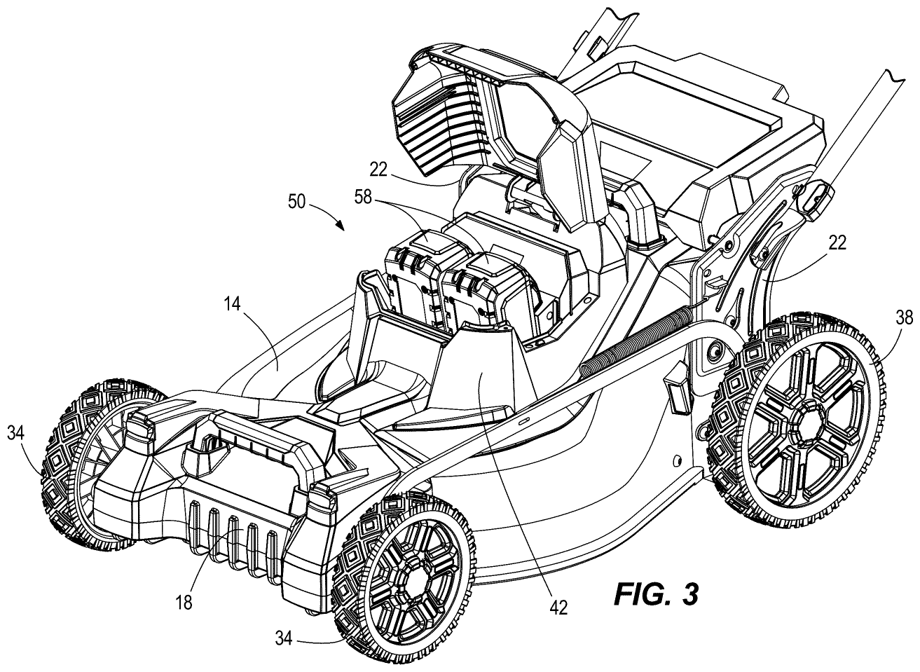

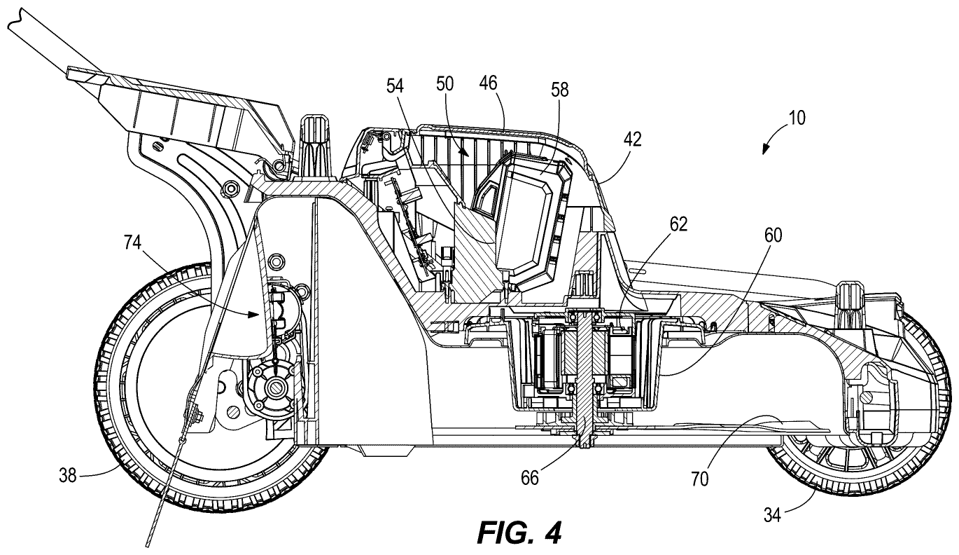

With reference to FIG. 3, the housing 12 further includes a battery housing 42 having a lid 46 (FIG. 2), which encloses a battery compartment 50. The battery compartment 50 includes two battery receptacles 54 (FIG. 4), each configured to receive a battery 58 (e.g., a rechargeable power tool battery pack having a nominal output voltage of 18-Volts) such that the batteries 58 are accommodated within the battery compartment 50 in a side-by-side arrangement (FIG. 3). The lid 46 is pivotably coupled to the battery housing 42 to provide an open and closed configuration of the battery housing 42. In the open configuration, the battery compartment 50 is accessible and allows the user to remove or insert the batteries 58 into the battery compartment 50. In the closed configuration of the battery housing 42, the batteries 58 are securely coupled to the battery receptacles 54 as the lid 46 encloses the battery compartment 50.

Referring to FIG. 4, the lawnmower 10 includes a motor housing 60 and a first motor 62 housed within the motor housing 60. The first motor 62 is supportably coupled to a center of the deck 14 and has an output shaft 66 coupled to a blade 70 with a tip defined at each end of the blade 70 configured to rotate to perform cutting operations. In the illustrated embodiment, the first motor 62 is configured to directly drive the blade 70. In other embodiments, the first motor 62 may drive the blade 70 through a transmission, belt drive, or any other suitable drive mechanism. The first motor 62 is powered by the batteries 58 that are coupled in series to the first motor 62. The first motor 62 is preferably a brushless direct current (BLDC) motor.

In the illustrated embodiment, the lawnmower 10 also includes a second motor 74 supportably coupled to the rear end portion of the deck 14. The second motor 74 is operably coupled to the rear wheels 38 (e.g., by a transmission 79, belt drive, or any other suitable drive arrangement) to selectively drive the rear wheels 38. As such, the lawnmower 10 may be configured as a rear-wheel-drive lawnmower 10. In other embodiments, the second motor 74 may be located in the front end portion of the deck 14 to selectively drive the front wheels 34, thereby configuring the lawnmower 10 as a front-wheel-drive lawnmower 10. In yet other embodiments, the second motor 74 may drive all four wheels 34, 38, or the second motor 74 may be omitted to configure the lawnmower 10 as a manual push mower. Like the first motor 62, the second motor 74 is also powered by the batteries 58.

The housing 12 of the lawnmower 10 is coated by the radioactive paint. Specifically, the battery housing 42 and the lid 46, which encloses the battery compartment 50, are coated with the radioactive paint. The deck 14 and the front frame 18 are also coated by the radioactive paint, thereby protecting the driving mechanism of the lawnmower 10, the first motor 62, the second motor 74, and the battery compartment 50 from heat provided by the surrounding environment. In other embodiments, the panel 28 of the handle 30 is also coated by the radioactive paint. In another embodiment, the radioactive paint only coats the lid 46 and the deck 14. In another embodiment, only the lid 46 is coated by the radioactive paint. In another embodiment, only the deck 14 and the panel 28 of the handle 30 are coated by the radioactive paint. In another embodiment, the radioactive paint is coated on the deck 14 and the front frame 18. In another embodiment, the radioactive paint only coats the battery housing 42 and the lid 46.

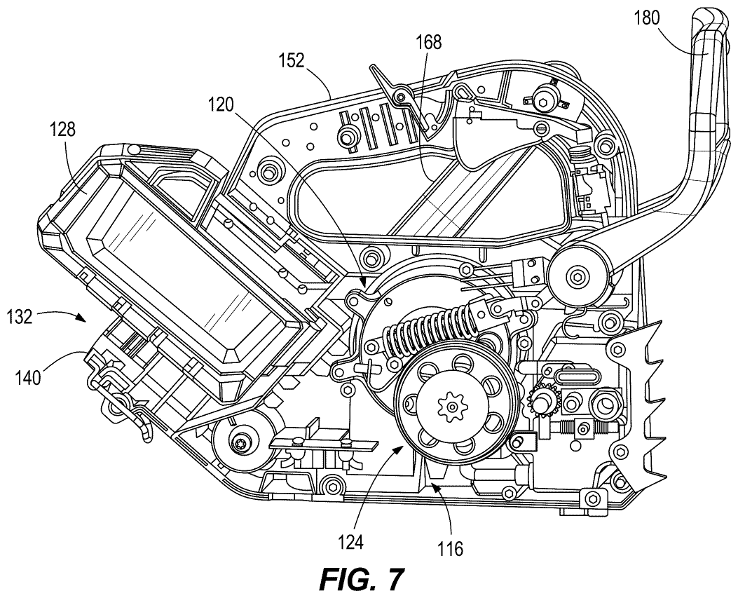

FIGS. 5-7 illustrates another electric device, such as a portable chainsaw 100. The chainsaw 100 includes a housing 104 and a guide bar 108 selectively coupled to the housing 104. The guide bar 108 supports a cutting chain 112 that is driven around the guide bar 108 by a power and drive assembly 116 (FIG. 7). The power and drive assembly 116 includes an electric motor 120 and a geartrain 124 supported within the housing 104.

A rechargeable battery pack 128 is selectively coupled to the chainsaw 100 for supplying power to the electric motor 120 to drive the geartrain 124. The battery pack 128 may include any of a number of different nominal voltages (e.g., 12V, 18V, etc.), and may be configured having any of a number of different chemistries (e.g., lithium-ion, nickel-cadmium, etc.). In particular, the housing 104 includes a battery pack receiving receptacle 132 formed at a rear portion of the housing 104. The battery pack receiving receptacle 132 includes a battery pack interface (not shown) positioned on a top surface of the battery pack receiving receptacle 132. The battery pack 128 is selectively coupled to the battery pack interface by moving the battery pack 128 through an opening 140 of the battery pack receiving receptacle 132. The battery pack receiving receptacle 132 is sized to accommodate different sized battery packs (e.g., battery packs including different heights). In addition, the battery pack receiving receptacle 132 includes apertures 144 formed through sidewalls 148 of the battery pack receiving receptacle 132. In some embodiments, the apertures 144 allow airflow into and out of the battery pack receiving receptacle 132 to aid in cooling the battery pack 128 during operation. In other embodiments, a cover can be movably coupled to the battery pack receiving receptacle 132 to selectively cover the battery pack 128 and the opening 140 to prevent debris from entering the battery pack receiving receptacle 132 during operation.

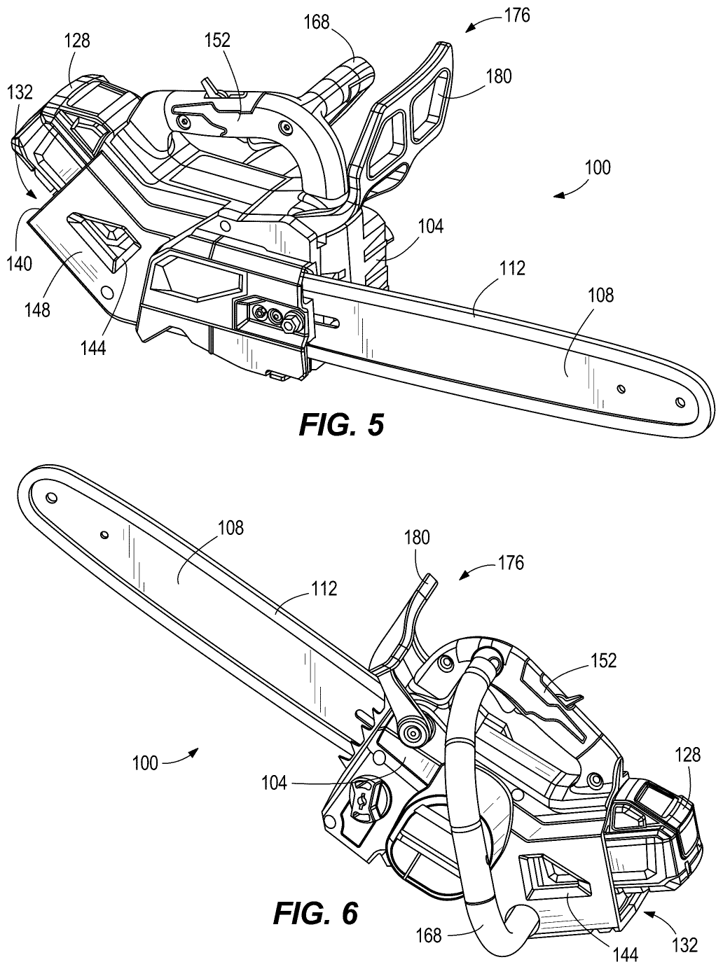

With continued reference to FIGS. 5 and 6, the illustrated housing 104 also includes a first handle 152 (e.g., a top handle) coupled between the battery pack receiving receptacle 132 and a front portion of the housing 104. The first handle 152 includes a trigger assembly 164 operable to actuate the electric motor 120. In addition, the housing 104 includes a second handle 168 (e.g., an elongated curved bar) coupled between the first handle 152 and a sidewall 148 of the battery pack receiving receptacle 132. The chainsaw 100 further includes a chain brake 176 having a handguard 180 pivotably coupled to the front portion of the housing 104 about a handguard pivot axis 184. The handguard 180 is located generally between the guide bar 108 and a front portion of the first handle 152. The chain brake 176 is operable to stop the movement of the cutting chain 112 and/or operation of the electric motor 120 during a kickback event.

The housing 104 of the chainsaw is covered by the radioactive paint. As such, the radioactive paint coats the exterior surface of the housing 104 to cover portions of the housing 104 that support the electric motor 120 and the gear train 124. The radioactive paint also covers a portion of the battery receptacle 132, such as the sidewalls 148 of the battery receptacle 132. In some embodiments, the radioactive paint only coats a portion of the housing 104 that supports the power and drive assembly 116. In other embodiments, the radioactive paint only coats the battery receptacle 132.

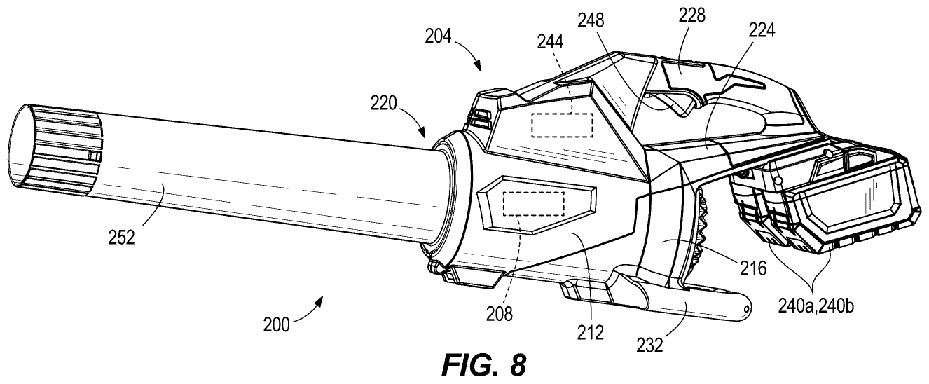

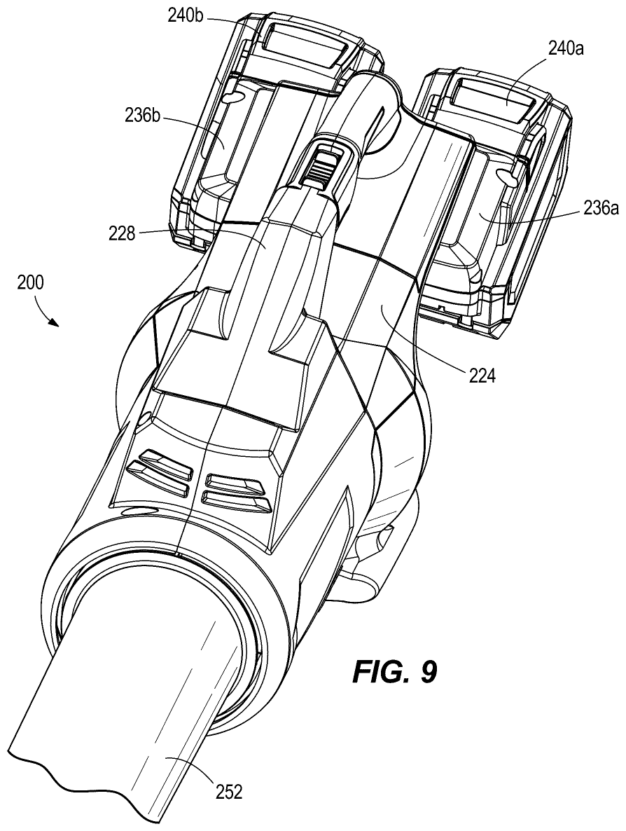

With reference to FIGS. 8 and 9, illustrates another electric device. The outdoor power tool of FIGS. 8 and 9 is a handheld blower 200 including a housing 204 configured to support a fan 208 within a fan portion 212 of the housing 204. The fan 208 includes an impeller and a motor. The housing 204 includes an inlet 216 disposed rearward of the fan 208 and an outlet 220 disposed forward of the fan 208. The housing 204 further includes a distal projection 224 and a handle portion 228. The distal projection 224 is disposed below the handle portion 228 and extends from the fan portion 212 in a direction away from the inlet 216. A front end of the handle portion 228 engages the fan portion 212, and a rear end of the handle portion 228 engages the distal projection 224. The housing 204 also includes a foot 232 configured to support the blower 200 upon a surface.

Two battery interfaces 236a, 236b are coupled to the distal projection 224. Each battery interface 236a, 236b respectively receives a battery pack 240a, 240b configured to power the fan 208. The battery interfaces 236a, 236b are electrically coupled to a printed circuit board assembly (PCBA) 244 supported within the housing 204. The PCBA 244 is further electrically coupled to the fan 208 and a trigger 248 coupled to the handle portion 228. The PCBA 244 is configured to receive a signal from the trigger 248 upon actuation of the trigger 248. As such, electrical power is drawn from the battery packs 240a, 240b through the battery interfaces 236a, 236b. The electrical power may be directed to power the fan 208. Accordingly, the fan 208 is operated, and fluid (e.g., air) is drawn through the inlet 216 and expelled (i.e., blown) from the outlet 220. In the illustrated embodiment, an exhaust tube 252 is coupled to the fan portion 212 to direct fluid expelled from the outlet 220.

The radioactive paint coats the housing 204 of the handheld blower 200. In particular, the radioactive paint coats the fan portion 212, the distal projection 224, the inlet 216, and the outlet 220. The battery interfaces 236a. 236b coupled to the distal projection 224 can also be covered by the radioactive paint. The placement of the radioactive paint can protect the motor, the fan 208, the PCBA 244, and other electrical components from heat provided by the surrounding environment. In some embodiments, the radioactive paint also coats the handle portion 228. In other embodiments, the radioactive paint only coats the fan portion 212. In another embodiment, the radioactive paint only coats the fan portion 212, the distal projection 224, and the handle portion 228.

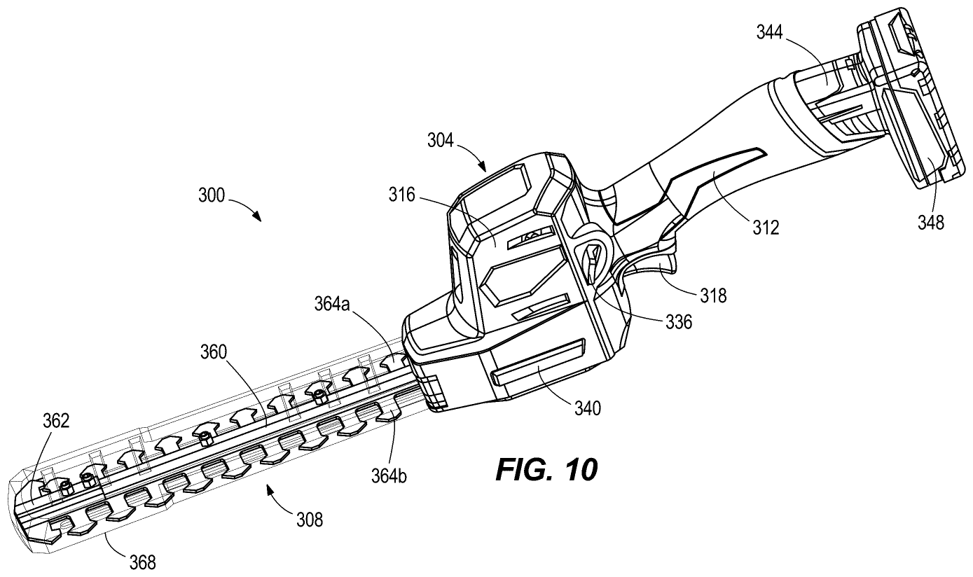

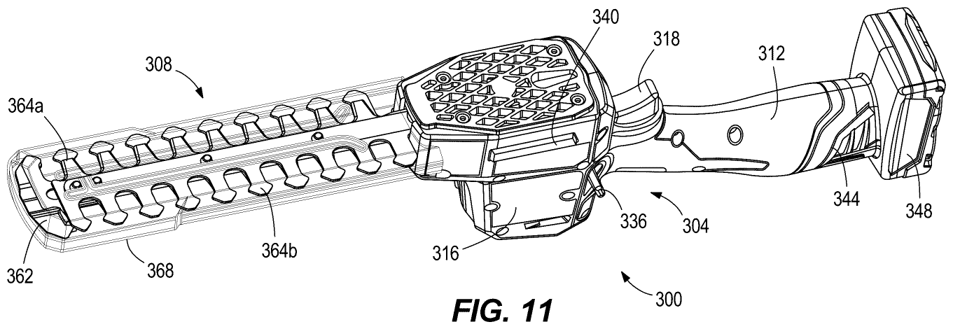

FIGS. 10 and 11 illustrates an electric device, such as a hedge trimmer 300. The hedge trimmer 300 includes a housing 304 and a blade assembly 308 for performing trimming. The housing 304 includes a handle portion 312 and a motor housing portion 316. The handle portion has a trigger 318 and is configured to be grasped by a user. The motor housing portion 316 supports a motor (not shown), a gear case (not shown), and a PCBA (not shown). The hedge trimmer 300 further includes a butterfly switch 336 and an overmold bumper 340 on each side of the motor housing portion 316. The butterfly switch 336 can be engaged to lockout the trigger 318. The overmold bumper 340 prevents marring.

The handle portion 312 includes a battery receptacle 344 configured to receive a battery pack 348. The battery pack 348 being configured to power the motor 320 upon actuation of the trigger 318. As such, the motor 320 is configured to drive the blade assembly 352. The blade assembly 352 includes a blade mounting washer (not shown), a blade spine 360, a blade tip guard 362, and two reciprocating blades 364a, 364b. The blade assembly 352 can be covered by a case 368 when the hedge trimmer 300 is not being operated. During operation, the blade assembly 352 moves reciprocally relative to the housing 304.

The exterior surface defined by the motor housing portion 316 of the hedge trimmer 300 is coated by the radioactive paint. A portion of the battery receptacle 344 is also coated by the radioactive paint. As such, the motor, the gear case, the PCBA, and a portion of the battery pack 348 are protected from heat that can be potentially absorbed by the hedge trimmer 300. In some embodiments, the handle portion 312 is also coated by the radioactive paint. In other embodiments, only the motor housing 316 is coated by the radioactive paint.

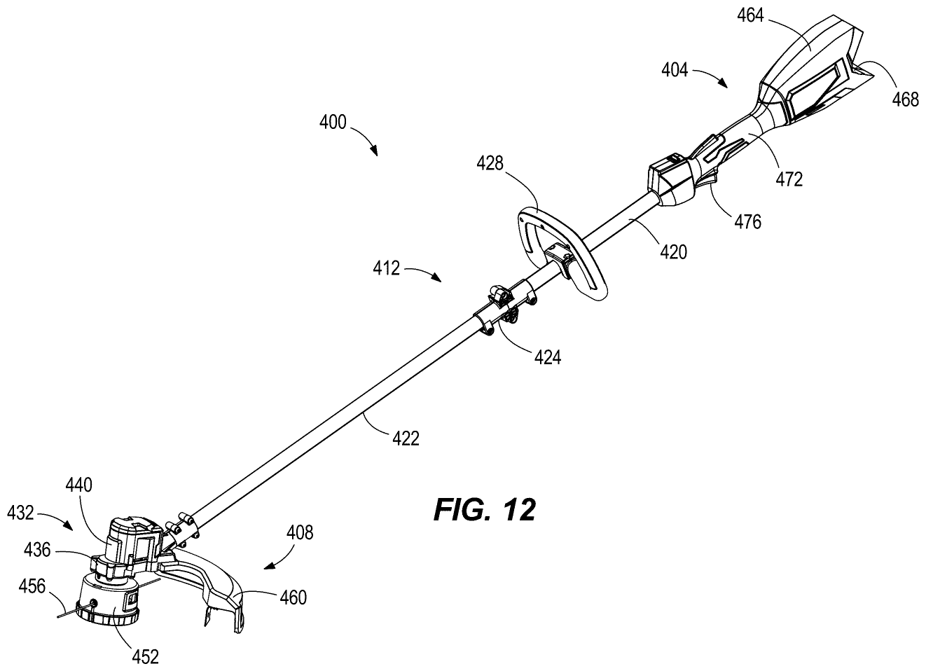

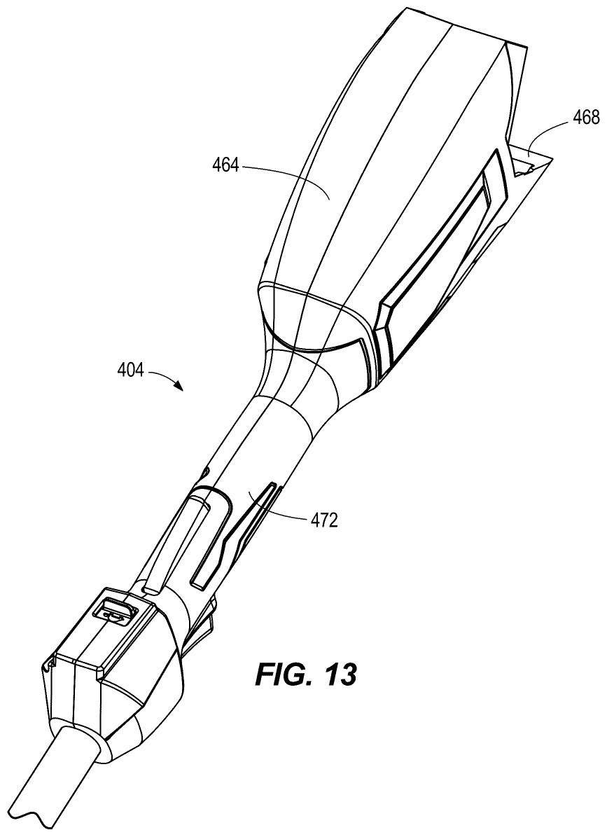

In reference to FIGS. 12 and 13, another electric device is illustrated. The electric device of FIGS. 12 and 13 is a string trimmer 400 including a handle unit 404 and a head unit 408 detachably coupled to the handle unit 404 by an elongated shaft assembly 412. The shaft assembly 412 includes a first shaft segment 420 affixed to the handle unit 404, a second shaft segment 422 affixed to the head unit 408, and a coupler 424 operable to couple the shaft segments 420, 422. The string trimmer 400 also includes a handle 428 coupled to the first shaft segment 420 and configured to be grasped by a user to hold the string trimmer 400 during operation.

The head unit 408 includes a head housing assembly 432 comprising a gear case 436 coupled to the second shaft segment 406, and a motor case 440 coupled to the gear case 436. The head unit 408 also includes an electric motor supported within the motor case 440, an output shaft rotatably coupled to a motor shaft of the electric motor, and a gear assembly that couples the motor shaft to the output shaft to provide a gear reduction therebetween. The head unit 408 further includes a trimmer head 452 supported on the output shaft. A flexible line of string 456 made from a suitable material, e.g., a plastic material such as nylon, is wound within the trimmer head 452 and includes one or more end portions extending outward from the trimmer head 452. As the trimmer head 452 rotates with the output shaft, the string 456 serves as a cutting blade, for example, to cut grass, weeds, or other vegetation as desired. The head unit 408 also includes a shroud 460 that protects the user from airborne debris stirred up during operation of the string trimmer 400.

The handle unit 404 includes a handle housing assembly 464, which may be formed by two clamshell housing halves. The handle housing assembly 464 define a compartment containing a counterweight (not shown) and other internal components (e.g., wiring, etc.) of the handle unit 404. The handle housing assembly 464 also includes a battery receptacle 468 configured to selectively mechanically and electrically connect to a rechargeable battery pack for supplying power to the string trimmer 400. The handle housing assembly 464 further defines a grip portion 472 (FIG. 13) supporting a trigger assembly 476 operable to selectively electrically connect the power source (e.g., the battery pack) and the motor.

The exterior surface defined by the handle housing assembly 464 of the string trimmer 400 is coated by the radioactive paint. The motor case 440 and the gear case 436 of the head housing assembly 432 are also coated by the radioactive paint. As such, the motor, gear reduction, and other components supported within the handle unit 404 and the head unit 408 are prevented from heating up. In some embodiments, only the handle unit 404 is coated by the radioactive paint. In other embodiments, only the head unit 208 is coated by the radioactive paint.

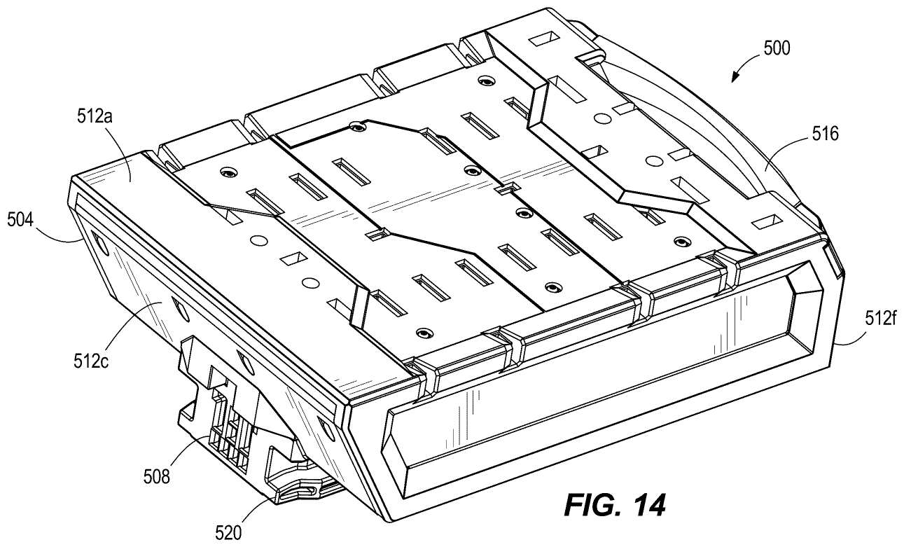

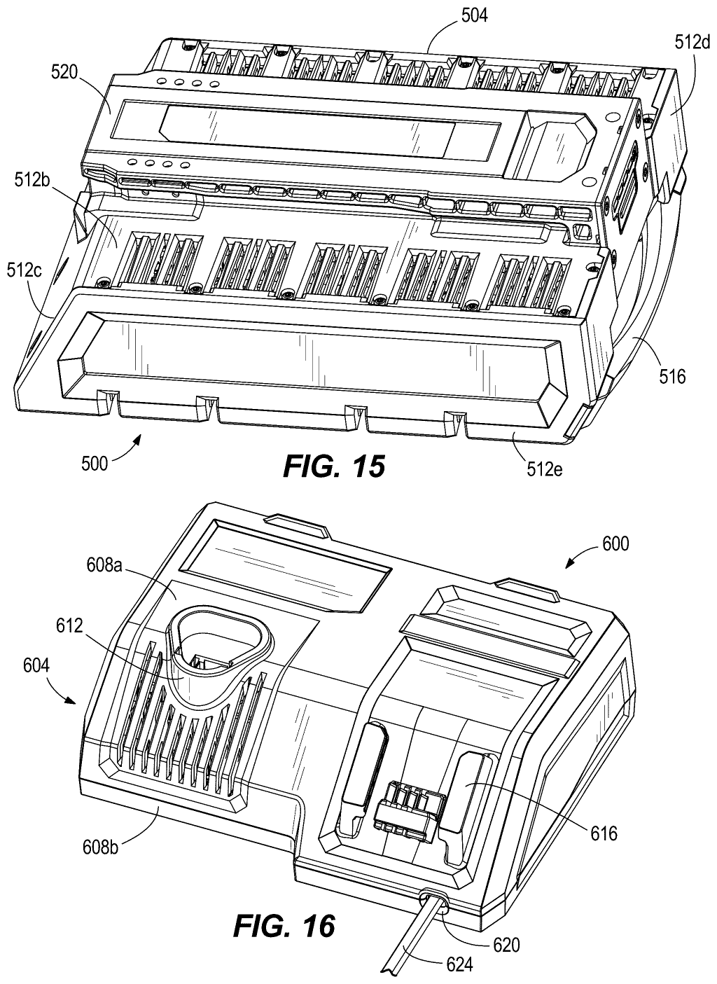

In reference to FIGS. 14 and 15, a battery pack 500 is illustrated. The battery pack 500 includes a housing 504 and an interface portion 508 for connecting the battery pack to a device (e.g., power tool, battery charger, etc.). The housing 504 is formed by sidewalls 512a, 512b, 512c. 512d, 512e, 512f, thereby providing the battery pack 500 with a rectangular structure. The housing 504 supports a battery controller and one or more battery cells having suitable chemistry for providing power to a device. The battery cells may be Lithium-ion, Nickel-Cadmium, or other suitable chemistry. A handle 516 is coupled to one of the sidewalls 512d and is configured to be grasped by a user when transporting the battery pack 500. The interface portion 508 is provided on a coupling portion 520 extending from one of the sidewalls 512b. The coupling portion 520 is configured to be slidably coupled to a device so that the interface portion 508 connects to the device so that the battery pack 500 powers a device or is charged by a battery charger.

The exterior surface defined by the housing 504 of the battery 500 is coated by the radioactive paint. In some embodiments, the radioactive paint is only used on the sidewalls 512a, 512b, 512c. 512d, 512e, 512f of the housing 504. In other embodiments, the radioactive paint is used on the sidewalls 512a, 512b, 512c, 512d, 512e, 512f of the housing 504, as well as the coupling portion 520. In another embodiment, the radioactive paint coats two sidewalls 512a, 512b and the coupling portion 520. In another embodiment, the radioactive paint coats four sidewalls 512c, 512d, 512e, 512f and the handle 516. In another embodiment, the radioactive paint only coats five side walls 512a, 512c, 512d, 512e 512f.

In reference to FIG. 16, a battery charger 600 is illustrated. The battery charger 600 includes a housing 604 having top portion 608a and a bottom portion 608b coupled to the top portion 608a (e.g., by fasteners). The housing portions 608a. 608b may be formed of plastic with each molded as a single piece. The housing 604 also provides a first support structure 612, a second support structure 616, a power input port 620 for connection to a power supply (e.g., through a power cord 624), and charger electronics. The first and second support structures 612, 616 each have terminals configured to electrically connect with a battery. The battery charger 600 is configured to charge a battery when the terminals of the support structures 612, 616 mate against terminals from the battery.

The housing 604 of the battery charger 600 is coated by the radioactive paint. In some embodiments, only the top portion 620a of the housing 604 is coated by the radioactive paint. In other embodiments, the top portion 620a and the bottom portion 620b of housing 604 are covered by the radioactive paint. In another embodiment, the radioactive paint only coats a portion of the top portion 620a in which the first and second support structures 612, 616 are located.

Although the disclosure has been described in detail with reference to certain preferred embodiments, variations and modifications exist within the scope and spirit of one or more independent aspects of the disclosure as described.

What is claimed is:

1. An electric device comprising:
a housing having an exterior surface exposed to a surrounding environment;
an interior volume defined in the housing;
an electronic component disposed in the interior volume and configured to generate heat; and
wherein at least a portion of the exterior surface emits infrared rays in a wavelength range of 8 to 13 micrometers to release heat into the surrounding environment.

2. The electric device of claim 1, wherein the portion of the exterior surface has an emissivity of at least 70 percent in the wavelength range.

3. The electric device of claim 2, wherein the emissivity is between 80 and 90 percent in the wavelength range.

4. The electric device of claim 3, wherein the emissivity is 88 percent in the wavelength range.

5. The electric device of claim 3, wherein the emissivity is 89 percent in the wavelength range.

6. The electric device of claim 2, wherein the portion of the exterior surface has an absorptivity of at least 3.5 percent for light having a wavelength range of 0.3 to 2.5 micrometers.

7. The electric device of claim 6, wherein the exterior surface of the housing is formed on a battery pack.

8. The electric device of claim 6, wherein the exterior surface of the housing is formed on a battery charger.

9. The electric device of claim 6, wherein the exterior surface of the housing is formed on a power tool.

10. The electric device of claim 9, wherein the power tool is configured to cut plant matter.

11. An electric device comprising:
a housing having an exterior surface exposed to a surrounding environment;
an interior volume defined in the housing; and
an electronic component disposed in the interior volume and configured to generate heat,
wherein at least a portion of the exterior surface emits infrared rays in a wavelength range of 8 to 13 micrometers, and
wherein the portion of the exterior surface includes at least one of Al₂O₂, SiO₂, and Si₃N₄ nanoparticles.

12. The electric device of claim 11, wherein the portion of the exterior surface includes dipentaerythritol penta-hexa-acrylate.

13. The electric device of claim 12, wherein the portion of the exterior surface includes an emissivity of at least 70 percent in the wavelength range.

14. The electric device of claim 13, wherein the exterior surface of the housing is formed on a battery pack.

15. The electric device of claim 13, wherein the exterior surface of the housing is formed on a battery charger.

16. The electric device of claim 13, wherein the exterior surface of the housing is formed on a power tool.

17. The electric device of claim 16, wherein the power tool is configured to cut plant matter.

18. An electric device comprising:
a housing having an exterior surface exposed to a surrounding environment;
an interior volume defined in the housing;
an electronic component disposed in the interior volume and configured to generate heat;
wherein at least a portion of the exterior surface emits infrared rays in a wavelength range of 8 to 13 micrometers to release heat into the surrounding environment, and
wherein the portion of the exterior surface includes at least one of Al₂O₂, SiO₂, CaSO₄, c-BN, ZrO₂, MgHPO₄, Ta₂O₅, AlN, LiF, MgF₂, HfO₂, and BaSO₄ nanoparticles mixed with a polymeric binder and a paint.

19. The electric device of claim 18, wherein the exterior surface of the housing is formed on a battery pack.

20. The electric device of claim 18, wherein the exterior surface of the housing is formed on a power tool.
